(19) United States
(12) Patent Application Publication
(10) Pub. No.: US 2008/0174337 A1
(43) Pub. Date: Jul. 24, 2008

(54) SYSTEMS AND METHODS FOR A DRIVE PREPARATION DEVICE

(76) Inventors: Steven Bress, Germantown, MD (US); Mark Joseph Menz, Folsom, CA (US); Daniel Bress, Germantown, MD (US)

Correspondence Address: Steve Bress, 7851-C Beechcraft Avenue, Gaithersburg, MD, 20879, US

(21) Appl. No.: 12/017,049

(22) Filed: Jan. 21, 2008

Related U.S. Application Data
(60) Provisional application No. 60/886,099, filed on Jan. 23, 2007.

(51) Int. Cl. H03K 19/00

(52) U.S. Cl. 326/8

(57) ABSTRACT

A physically small, inexpensive to manufacture stand-alone dedicated function drive preparation device connects to a long term storage device such as a hard drive. The drive preparation device performs operations on the storage device such as formatting, copying, verifying, configuring, testing, and cleaning. Additionally the device may be configured set passwords. The device may also be configured to make multiple copies of a source storage device, these copies having unique network identifications. The device may be configured by a user.

### RELATED APPLICATION

This application claims priority under 35 U.S.C. § 119 based on U.S. Provisional Application No. 60/886,099, filed Jan. 23, 2007, the disclosure of which is incorporated herein by reference.

### BACKGROUND OF THE INVENTION

A. Field of the Invention

The present invention relates to computer memory devices and, more specifically, to improved mechanisms for preparing them for use, such as copying, formatting, and cleaning.

B. Description of Related Art

The occurrence of Malware being found on new computer equipment has been increasing. This leads to a need to ensure that new equipment is free of Malware. This may be done in-house by copying devices known in the art. One knowledgeable in the art can anticipate that new businesses will form to clean and certify new equipment is free of Malware. This leads to a need to verify that new equipment is indeed free of Malware. Thus Information Technology personnel may send a shipment of new hard drives to a Cleaning Company to ensure the drives do not have Malware. Upon receiving the drives back from the cleaning company, the IT personnel may desire to test some or all of the cleaned hard drives to verify there is no Malware on them.

Computer forensic technicians are often tasked with storing hard drives confiscated by law enforcement officials. These hard drives are often stored by themselves, not connected to a computer. These drives must be stored but available in working order for years. Hard drive manufacturers recommend spinning up hard drives at predetermined intervals. There is no current solution for this situation in the art.

Information Technology (IT) personnel are often tasked with getting computers configured and ready for use that have no operating systems installed. Additionally IT personnel are tasked with getting recycled computers to a known state. At the end of a semester lab computers are often required to be set to a known state. When IT personnel are tasked with concurrently configuring multiple computers, their need is currently addressed in the art by expensive devices such as Logicube's OmniClone® 15U http://www.logicube.com/products/hd_duplication/omniclone15u.asd. This device is able to copy data to 15 drives at once. Note, installing operating systems on new equipment is just one example of the need to copy data to a computer memory device.

State of the art hardware drive copiers are characterized by the requirement to remove a hard drive from a computer and physically attach the drive to a copying device. Logicube's® product line http://www.logicube.com/ is a good example of current art. These drive copiers are expensive. The process of removing a hard drives from a computer, hooking it up to a drive copier and subsequently re-installing it into the computer is time consuming and puts the hard drive at risk of damage. Additionally, there must be means to ensure that the correct drive is put back in the proper computer. There are four important factors to consider in a drive preparation device:
Cost,
Ease of use,
Functionality and
Drive protection.

Accordingly, there is a need in the art for an improved drive preparation device.

### SUMMARY OF THE INVENTION

Systems and methods consistent with the present invention address these and other needs by providing for operating system independent circuitry and logic that is physically connected to a storage device.

Please refer to FIG. 1. The current invention, an improved drive preparation device 103 is connected through a drive cable 102 to a destination memory device 101. The operating system independent logic and circuitry 103, issues commands to the destination memory device 101 to perform various functions such as: format, install software, clean, verify, or set a password. The logic and circuitry may be contained in a protective device such as a case. The improved drive preparation device is very small in size and inexpensive to manufacture.

The improved drive preparation device may have a second drive cable 104, which connects a source memory device 105. This source memory device may be any type of memory device, such as a hard drive or digital media. In the case of digital media 104 would be a digital media interface. The source memory device allows additionally functionality such as: installing an operating system, creating an exact copy of a source device, and/or copying a drive image, among others.

The improved drive preparation device may physically include source memory device 105. This may take the form of as such devices as a memory stick reader, a mini-drive, or a micro-drive. A full size drive may be included as well.

The improved drive preparation device may include logic to perform tests on destination memory device 101 and means to indicate to a user the results of a test. The means may be LED lights and/or an additional computer port to report results to a PC. Additionally, LED lights may be used to indicate status of the improved drive preparation device.

The improved drive preparation device may include user input devices, such as switches. This would allow additionally functionality such as allowing a user to select what type of drive configuration to perform such as FAT, FAT32, HFS, etc. The improved drive preparation device may be built with a specific function, such as drive cleaning. Or it may be fully functioned with a user input device such as a switch allowing a user to choose which function to use.

The improved drive preparation device may include both a source memory device and user input devices. This would allow the additional functionality of giving a user a choice of what software to copy from the source memory device.

One use for the improved drive preparation device is to clone an existing drive. A problem arises that cloned machines would have the same network ID as the original. The improved drive preparation device may include a method for creating unique network IDs for multiple drives cloned from one drive.

The improved drive preparation device may be configured to take power from standard PC connections, to take power from an AC Adapter and/or to take power from a battery.

The improved drive preparation device may perform operations on “hidden” areas of the storage device such as Host Protected Areas.

### BRIEF DESCRIPTION OF THE DRAWINGS

The present invention is illustrated by way of example and not limitation in the figures of the accompanying drawings, in which like references indicate similar elements and in which:

FIG. 1 is a block diagram illustrating an improved drive preparation device;

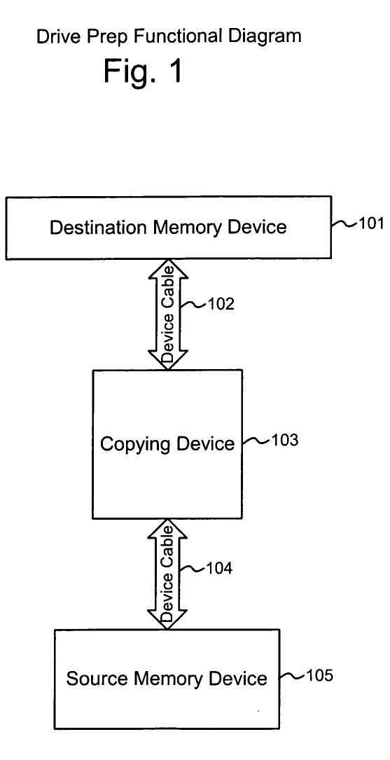

FIG. 2 is a detailed diagram showing one embodiment of the circuitry required to make an improved drive preparation device.

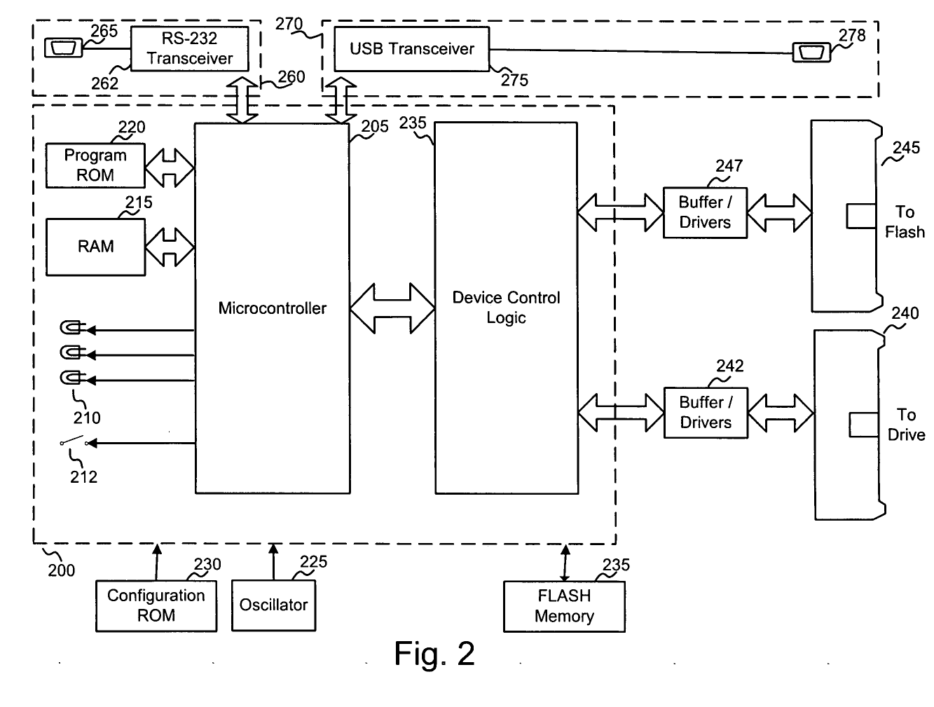

FIG. 3 is a flowchart showing the logic flow of the improved drive preparation device.

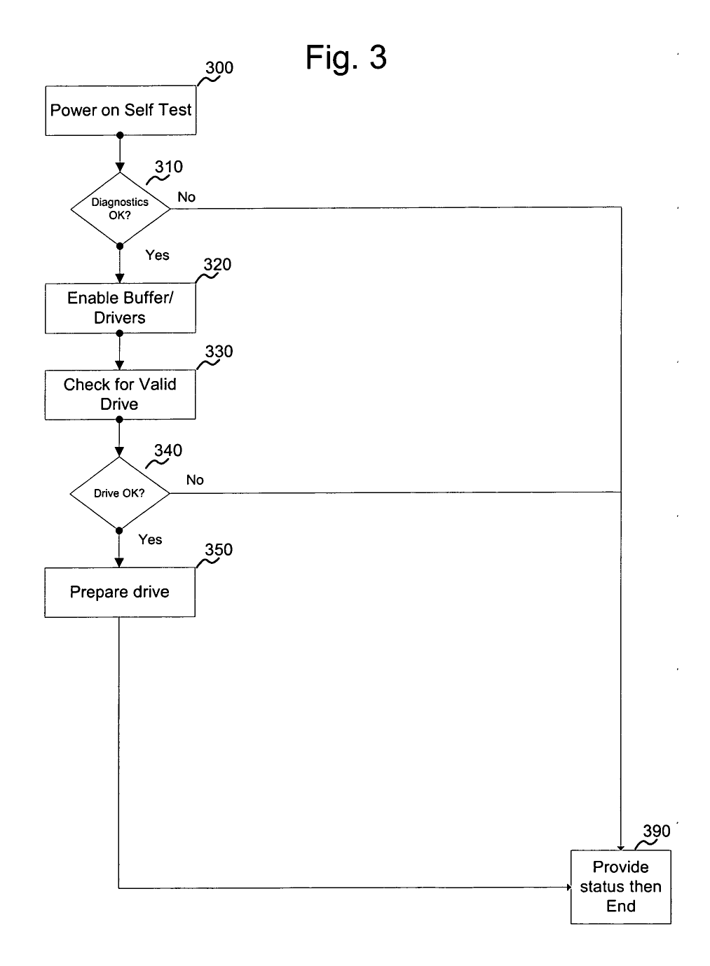

### DETAILED DESCRIPTION

The following detailed description of the invention refers to the accompanying drawings. The same reference numbers in different drawings identify the same or similar elements. Also, the following detailed description does not limit the invention. Instead, the scope of the invention is defined by the appended claims and equivalents.

An improved drive preparation device is described herein that is inexpensive to manufacture, physically small in size, able to connect to a long-term memory storage device without removing said device from a computer, and perform actions upon the long-term memory storage device. The improved drive preparation device has logic and circuitry to enable it to perform such actions as: formatting, configuring, copying, testing, verifying, and cleaning. The improved drive preparation device may have a source memory. The improved drive preparation device has an interface port through which it can communicate with a long-term memory device.

For the sake of this discussion, the long-term storage device is an ATA hard drive, and the Source Memory device is a Compact Flash card.

In order to keep the design of the invention simple, much of the circuitry is encapsulated in a single FPGA 200, such as the Altera Cyclone® II EP2C5F256C8N. Altera® provides the design files for use with this FPGA to create a microcontroller 205 called NIOS. The processor only takes a portion of the available logic within the FPGA.

Additional logic in the FPGA is used to create the Drive and Source device control logic 235. In this example, both interfaces may be substantially similar, as a CompactFlash device is capable of emulating an ATA drive. The Device control logic is designed to be a Host Drive controller in order to support a standard IDE drive.

In some cases, the FPGA could directly interface with an IDE drive without the need for additional buffers and drivers. Modern hard drives use 3.3V signaling on the ATA port, and that is compatible with the FPGA outputs. However, there is no guarantee that the user will plug in a modern drive, and plugging in an older drive could exceed the maximum design ratings for the FPGA. For this reason, additional buffers/drivers 247 and 242 are used to act as voltage level translators to insure that safe voltages are presented both to the FPGA and the attached long term storage devices. High speed bus switches, such as IDT's IDTQS316211 are used both as isolation devices during the power on sequencing of the invention and voltage translators. Since the bus switches may be disabled, there is effectively no connection between the device control logic and the attached storage device until the invention has powered up properly and enabled the bus switches.

The FPGA is configured upon power up by its configuration ROM 230, which may be an Altera® EPCS1SI8. As part of this configuration, the program ROM 220 for the NIOS processor is loaded with the code to run the Microcontroller. Additional logic within the FPGA is used to provide RAM 215 to the NIOS processor.

Part of the embedded processor design of the FPGA includes logic for implementing an RS-232 interface, which is buffered by transceiver 262 before being presented to a connector 265 for an external interface. Similarly, USB interface circuitry is created as part of the embedded processor design, and buffered by USB transceiver 275 before being presented to a connector 278 for an external interface.

In operation, the USB port may be used for connection to an external PC for configuration and control functions as may be desired. Configuration data, if any, may be stored in FLASH memory 235 for non-volatile storage. The RS-232 port may be used to connect to a printer or other peripheral for status reporting or other communication functions.

Operational status is supplied by LEDs 210 which are controlled by logic and circuitry in FPGA 200. Switch 212 is used for direct user input to the Microcontroller 205. Depending on the configuration, the switch may indicate that a specific function should commence or that status should be returned.

When the unit is powered on, the microcontroller performs a self-test 300 to insure that the system is in a known good state. If the self-test fails in any way, status is provided and program execution terminates 390. If the system checks out OK, the Buffer/Driver modules 242 and 247 are enabled 320.

Once the Buffer/Drivers are enabled, the attached drive is detected and tested 330. If there is a problem with the drive, status is provided and program execution terminates 390. If the drive is OK, then preparation of the drive begins. Whether the preparation succeeds or fails, status is provided and program execution terminates 390.

The improved drive preparation device has logic and circuitry to enable it to perform such actions as: formatting, configuring, copying, testing, verifying, and cleaning. One knowledgeable in the art will understand that there are multiple methods known in the art to format a storage device, to copy a storage device and to clean a storage device.

Verifying. The improved drive preparation device may verify that a drive has a specific bit pattern written to it, such as all 0's. Thus a drive could be quickly verified that it is clean. Additionally the device may verify specific portions of a drive.

Testing. The simplest embodiment of testing may be for the improved drive preparation device to test if a storage device is operational. There are many other tests known in the art. In order to test if a hard drive is operational it must be spun up to speed and then at least one write then read operation is performed. Drive manufacturers recommend that hard drives be spun up at regular intervals to ensure proper functioning. Back up hard drives and hard drives being held in evidence are just two examples of hard drives that may removed from a computer system, yet still need to be spun up at regular intervals. In another embodiment the device may spin up a hard drive at preset intervals. In the case of testing an evidence drive, only the read test would be performed so as not to risk any of the data on the drive.

Hidden Areas. Storage devices may have hidden areas such as the Integrated Drive Electronics (IDE) Host Protected Area (HPA). The improved drive preparation device may be configured to access hidden areas. The device may prepare data in a hidden area of a storage device. On an IDE drive, there are a couple of methods that may be used. One is to prepare the entire drive, then set a Host Protected Area active at an appropriate location. The other method is to set a Host Protected Area active then switch to the protected area. The newly active area may then be prepared like any other area on the drive. It may then be swapped back out, effectively hiding it from any operating system. This technique may be used by a manufacturer to ship a clean version of an application, such as an operating system, that is protected from the user of the drive. In an emergency, a specialized software application may recover data from the hidden area of the drive.

Although concepts consistent with the present invention are primarily described herein in relation to an IDE magnetic hard disk drive, these concepts may be implemented with other types of drives such as SATA, FireWire, USB, and parallel ATA. For the sake of clarity, the remaining description herein will be described with reference to an IDE magnetic hard drive, although the concepts of the invention are not limited to such drives. One skilled in the art would appreciate that other modern long-term storage device interfaces share similar functionality that could be incorporated into the concepts described herein.

### The Preferred Embodiment

### Single Interface, No User Input

One simple embodiment of the improved drive preparation device, has a single interface, a drive cable, a power socket, no user input devices, and two LEDs. This embodiment may be configured at the factory to do a specific task(s) such as the following sequence: format drive; install free DOS OS; then install Bootloader for remote imaging. The improved drive preparation device may be user configurable by connecting it to a PC with the appropriate software, to allow a user to specify a specific task(s) such as the following sequence: securely clean drive, then format drive. This device may be so small that it is able to fit into the head of a drive cable.

Once this embodiment of the improved drive preparation device has been configured, an end user performs the following steps:
1. Disconnect drive interface cable from destination memory device 102.
2. Connect Drive Preparation Device interface cable 102 to destination memory device 102.
3. Connect a computer power cable to drive preparation device.
   Upon receiving power the device initiates performing its task(s). The improved drive preparation device may light an LED to indicate the device is on and light another LED to indicate the device has performed its task.

The logic and circuitry of the improved drive preparation device includes non-volatile memory. The amount of memory can be increased by the additional of additional memory chips, which would make the device slightly larger.

A single interface, no user input, improved drive preparation device facilitates relatively unskilled personnel in performing drive preparation tasks.

### One Interface, User Input

Additionally functionality may be added to the improved drive preparation device by the addition of a switch or switches. A switch may allow a user to select between various degrees of drive cleaning. A switch may allow a user to select which format type to apply, such as FAT, FAT32, HFS, etc.

### Two Interfaces No User Input

Should the amount of data desired to be copied using the improved drive preparation device be greater than the amount of onboard memory, a solution would be to add a second interface 104 to connect to a source memory device 105. Source memory device 105 may be any type of non-volatile memory; there is no functional difference between them except for physical size. One advantage for not having a means for user input is to allow minimally trained personnel to correctly use the device.

### Two Interfaces User Input

Additionally functionality can be added to the improved drive preparation device by the addition of a switch or switches. A switch may allow a user to select between different drive images on the source drive to copy to the destination drive.

### SUMMARY

As described above, a drive preparation device is connected to a storage device. The drive preparation device may perform such actions as: formatting, configuring, copying, testing, verifying, and cleaning of the connected storage device. Logic and circuitry within the drive preparation device controls functionality of the drive preparation device. The functionality of the embedded processor can be programmably modified to allow for a number of different possible drive preparation options.

It will be apparent to one of ordinary skill in the art that the embodiments as described above may be implemented in many different forms of software, firmware, and hardware in the implementations illustrated in the figures. The actual software code or specialized control hardware used to implement aspects consistent with the present invention is not limiting of the present invention. Thus, the operation and behavior of the embodiments were described without specific reference to the specific software code, it being understood that a person of ordinary skill in the art would be able to design software and control hardware to implement the embodiments based on the description herein.

The foregoing description of preferred embodiments of the present invention provides illustration and description, but is not intended to be exhaustive or to limit the invention to the precise form disclosed. Modifications and variations are possible in light of the above teachings or may be acquired from practice of the invention.

No element, act, or instruction used in the description of the present application should be construed as critical or essential to the invention unless explicitly described as such. Also, as used herein, the article “a” is intended to include one or more items. Where only one item is intended, the term “one” or similar language is used.

The scope of the invention is defined by the claims and their equivalents.

What is claimed:

1. A physically small, inexpensive to manufacture, stand-alone dedicated function, drive preparation device comprising:
an interface for connecting to a long term storage device; and
logic and circuitry coupled to the interface, the logic and circuitry configured to issue one or more command sets to the storage device, the command sets causing the storage device to be formatted, configured, tested, written to, verified and/or cleaned.

2. The drive preparation device of claim 1, further comprising: a second interface coupled to the logic and circuitry for connecting to a source long term storage device.

3. The drive preparation device of claim 1, further comprising: a digital media reader coupled to the logic and circuitry.

4. The drive preparation device of claim 1, wherein the logic and circuitry is configured to create unique network identification for multiple drives cloned from a single source drive.

5. The drive preparation device of claim 1, wherein the logic and circuitry is configured to perform operations on hidden areas of the long term storage device.

6. The drive preparation device of claim 1, further including light emitting diodes (LEDs) coupled to the logic and circuitry and configured to transmit status information relating to the status of the drive preparation device.

7. The drive preparation device of claim 1, further including one or more switches.

8. The drive preparation device of claim 1, further comprising: a third interface coupled to the logic and circuitry for the purpose of communicating and/or accepting input from a user.

9. The drive preparation device of claim 1, wherein the logic and circuitry is configured to spin up a hard drive coupled to the long term storage interface at preset intervals.

10. The drive preparation device of claim 1, wherein the logic and circuitry is configured to set a password.

11. The drive preparation device of claim 1, wherein the logic and circuitry is configurable by a user.
